(19) United States
(12) Patent Application Publication
(10) Pub. No.: US 2002/0121947 A1
(43) Pub. Date: Sep. 5, 2002

(54) Monolithic microwave integrated circuit and method of manufacturing the same

(76) Inventors: Dong-sik Shim, Seoul (KR); Sang-goog Lee, Incheon Metropolitan-City (KR)

Correspondence Address: STAAS & HALSEY LLP, 700 11TH STREET, NW, SUITE 500, WASHINGTON, DC, 20001, US

(21) Appl. No.: 09/984,892

(22) Filed: Oct. 31, 2001

(30) Foreign Application Priority Data
Mar. 3, 2001 (KR) 2001-11012

(51) Int. Cl. H01P 1/00

(52) U.S. Cl. 333/247; 257/728

(57) ABSTRACT

A monolithic microwave integrated circuit (MMIC) includes a semiconductor substrate, active and passive devices formed on the semiconductor substrate, a dielectric layer formed to cover the active and passive devices on the semiconductor substrate, and a ground plane formed on the dielectric layer to ground the active device through the dielectric layer.

### CROSS-REFERENCE TO RELATED APPLICATIONS

This application claims the benefit of Korean Application No. 2001-11012, filed Mar. 3, 2001, in the Korean Industrial Property Office, the disclosure of which is incorporated herein by reference.

### BACKGROUND OF THE INVENTION

1. Field of the Invention

The present invention relates to a monolithic microwave integrated circuit (MMIC) and a method of manufacturing the same, and more particularly, to an MMIC with a novel ground plane and a method of manufacturing the same.

2. Description of the Related Art

Monolithic microwave integrated circuits (MMICs), which include active and passive devices formed on a single substrate by batch processing, are used to amplify small amplitudes of signals and change frequencies. MMIC manufacturing techniques are considered to be paramount to increasing the yield of microwave systems by reducing the number of constituent parts as well as enabling the production of small, light-weight systems.

For an MMIC, interconnects between unit devices, as well as the active and passive devices, on a semiconductor substrate are made by batch processing. Thus, the size of an MMIC board is smaller than a conventional high-frequency circuit board having a high reliability and consistent characteristics. Also, MMICS do not require separate packages of individual parts, which lowers the manufacturing cost as compared to the manufacturing cost of a conventional high-frequency circuit that uses separate packages of parts.

Unlike general microwave circuits, which must be made from parts which are available in a limited number of device packages, the shape and size of a device of an MMIC can be controlled by a designer. Thus, an optimal-performance MMIC can be manufactured for a specific use. The manufacturing cost of MMICs is unaffected by an increase in the number of active devices, and thus there is an advantage of diversifying the circuit configuration.

A conventional MMIC is shown in FIG. 1. A semiconductor substrate 10 is formed to be thin enough to prevent coupling of signals between transmission modes at ultra high frequencies in the tens of Gigahertz. Reference numeral 12 represents an active device formed on the semiconductor substrate 10 and reference numeral 14 represents a microstrip line that interconnects the active device 12 and a passive device (not shown) in the semiconductor substrate 10. An opening 16 is formed in the semiconductor substrate 10 and a ground plane 18 is formed beneath the semiconductor substrate 10 such that it contacts the microstrip line 14 through the opening 16.

As described above, for conventional MMICs, the substrate 10 is formed to be thin to prevent coupling of signals between transmission modes. For example, it is preferable that the semiconductor substrate 10 has a thickness of 100 μm or less at ultra high frequencies of tens of Gigahertz. To obtain a semiconductor substrate 10 as thin as 100 μm or less, the formation of the active and passive devices in the semiconductor substrate 10 should be followed by etching or polishing the back of the semiconductor substrate 10. However, adjusting the thickness is difficult and such a thin semiconductor substrate of tens of micrometers is easily broken. Thus, the semiconductor substrate must be carefully handled so as not to reduce yield. In addition, a dielectric loss caused by the dielectric constant of the semiconductor substrate is large, thereby increasing signal loss.

### SUMMARY OF THE INVENTION

To solve the above and other problems, it is an object of the present invention to provide a monolithic microwave integrated circuit (MMIC) that reduces signal loss caused by dielectric loss and preventing a drop in yield.

It is another object of the present invention to provide a simple method of manufacture for an MMIC that does not need etching or polishing of the back of a semiconductor substrate, which is otherwise required to prevent coupling of signals between transmission modes after formation of the active and passive devices of the MMIC.

Additional objects and advantages of the invention will be set forth in part in the description which follows and, in part, will be obvious from the description, or may be learned by practice of the invention.

To achieve the above and other objects, an MMIC according to an embodiment of the present invention includes a semiconductor substrate, active and passive devices formed on the semiconductor substrate, a dielectric layer formed to cover the active and passive devices on the semiconductor substrate, and a ground plane formed on the dielectric layer to ground the active device through the dielectric layer.

According to an aspect of the present invention, the ground plane grounds the active device through a contact hole formed in the dielectric layer.

According to another embodiment of the present invention, a method of manufacture for an MMIC includes forming active and passive devices on a semiconductor substrate such that the active and passive devices are interconnected, forming a dielectric layer to cover the active and passive devices on the semiconductor substrate, and forming a ground plane on the dielectric layer to ground the active device.

According to another aspect of the present invention, the active and passive devices are interconnected by a microstrip line.

According to a further aspect of the present invention, the forming the ground plane includes forming a contact hole through which the microstrip line is exposed in the dielectric layer, and forming a conductive layer on the dielectric layer in which the contact hole is formed to form the ground plane connected to the microstrip line through the contact hole.

According to a still further aspect of the present invention, the dielectric layer is a polymer layer.

### BRIEF DESCRIPTION OF THE DRAWINGS

The above and other objects and advantages of the present invention will become apparent and more readily appreciated by describing in detail preferred embodiments thereof with reference to the enclosed drawings in which:

FIG. 1 is a sectional view of a conventional monolithic microwave integrated circuit (MMIC);

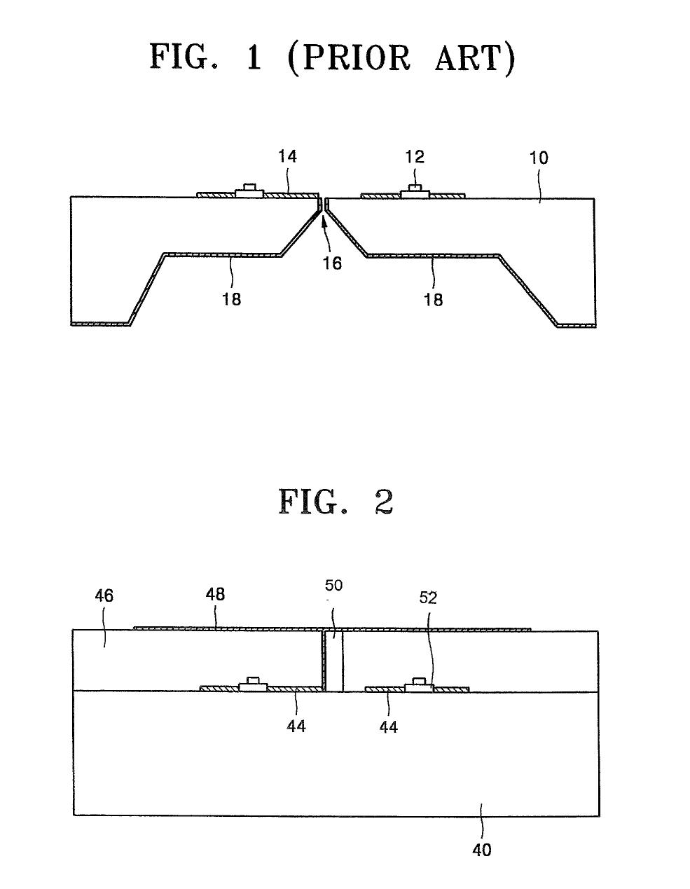

FIG. 2 is a sectional view of an embodiment of an MMIC according to the present invention; and

FIGS. 3 through 6 are sectional views illustrating a method of manufacturing the MMIC of FIG. 2 according to an embodiment of the present invention.

### DETAILED DESCRIPTION OF THE PREFERRED EMBODIMENTS

Reference will now be made in detail to the present preferred embodiments of a monolithic microwave integrated circuit (MMIC) and a method of manufacturing the same according to the present invention, examples of which are illustrated in the accompanying drawings, wherein like reference numerals refer to the like elements throughout. The embodiments are described below in order to explain the present invention by referring to the figures. In the drawings, the thickness of layers and regions are exaggerated for clarity.

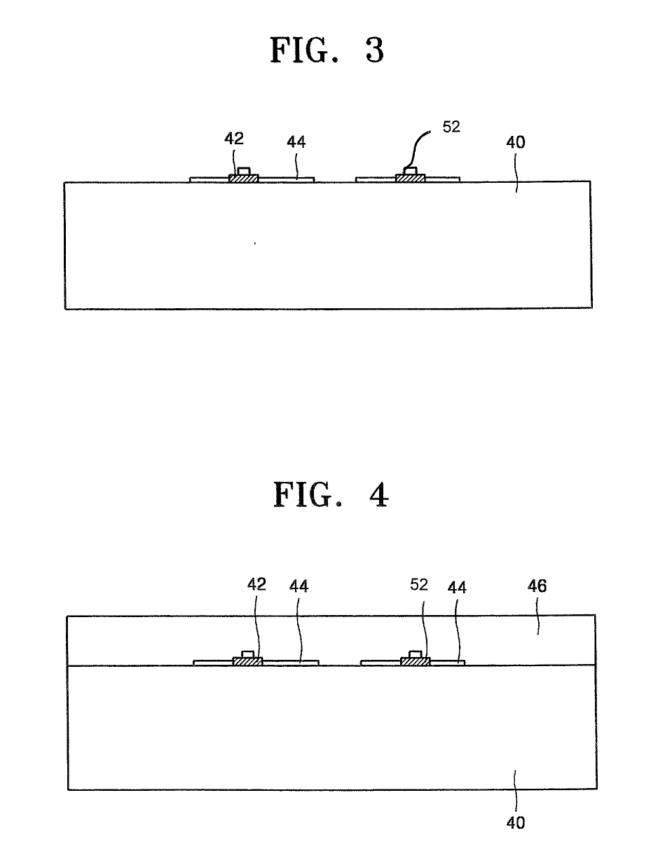

FIG. 2 shows an MMIC according to an embodiment of the present invention. A semiconductor substrate 40 is formed of a silicon substrate (preferably of a III-V compound semiconductor substrate) which is chosen taking into account that an MMIC terminal that needs a small, light-weight, and be a low-power consumption RF device. For example, the semiconductor substrate 40 may be a GaAs substrate. Although not a III-V compound, an SiGe substrate can be used as the semiconductor substrate 40.

An active device 42, such as a high-frequency transistor, is formed on the semiconductor substrate 40. A passive device 52, such as a capacitor or an inductor, is formed on the semiconductor substrate 40. The active device 42 and passive device 52 are interconnected on the semiconductor substrate 40. A dielectric layer 46 having a predetermined thickness is formed to cover all the devices 42 and interconnect microstrip lines 44 formed on the semiconductor substrate 40. Preferably, the dielectric layer 46 is formed of a polymer layer, such as a polyimide or a photoresist layer. A contact hole 50 through which a microstrip line 44 is exposed is formed in the dielectric layer 46. A ground plane 48 is formed on the dielectric layer 46 such that the ground plane 48 is connected to a portion of the microstrip line 44 exposed through the contact hole 50. As shown in FIG. 2, the ground plane 48 extends along the sidewall of the contact hole 50 such that it contacts the microstrip line 44. Alternatively, it is understood that the ground plane 48 may be connected to the microstrip line 44 by a conductive plug (not shown) filing the contact hole 50.

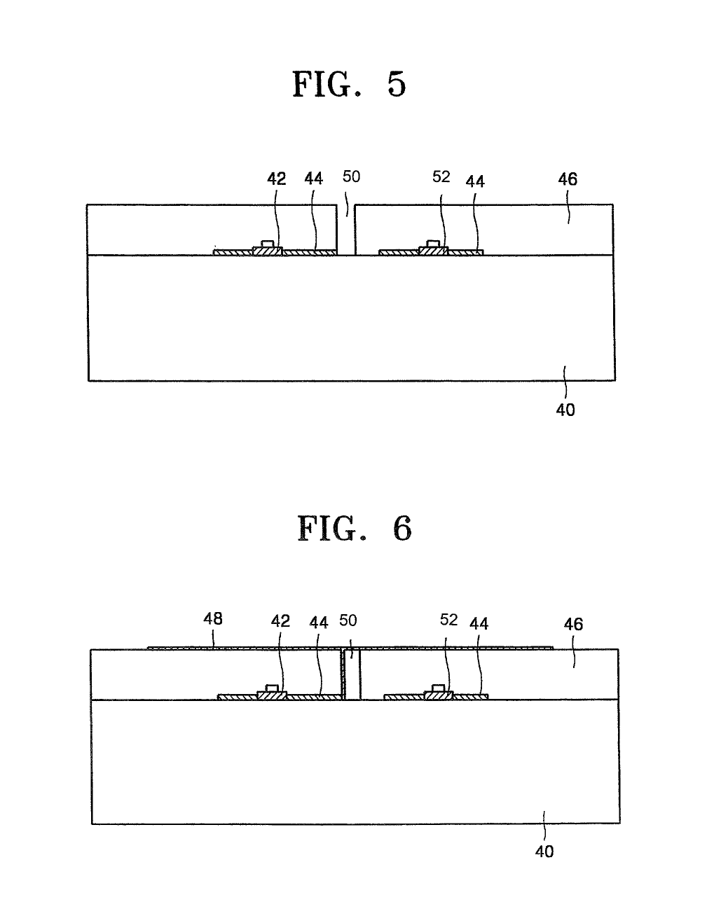

The MMIC according to the present invention is manufactured according to the following method shown with reference to FIGS. 3 through 6.

Referring to FIG. 3, the active device 42 and passive device (not shown) are formed on the semiconductor substrate 40. A microstrip line 44 is formed to interconnect the active device 42 and passive device 52. The semiconductor substrate 40 may be formed of a silicon substrate for a relatively low-frequency device. Preferably, the substrate 40 is a III-V compound semiconductor substrate such as a GaAs substrate. Although not a III-V compound, an SiGe substrate can also be used as the semiconductor substrate 40.

The active device 42 is a transistor such as a high-frequency metal semiconductor field effect transistor (MESFET). This MESFET may be formed by performing selective implantation of a substrate with GaAs ions, activating the GaAs ions to form a channel region in the substrate, etching the substrate to form a recess for appropriate characteristics, and forming a metal gate in the recess. As described above, the active device 42 may be formed through a semiconductor device manufacturing process. As an example of the passive device 52, a capacitor or inductor is formed on the semiconductor substrate 40.

Next, as shown in FIG. 4, a dielectric layer 46 is formed to cover the active device 42, the microstrip line 44, and the passive device on the semiconductor substrate 40. It is preferable that the dielectric layer 46 is formed of a polymer layer, such as a polyimide layer or a, photoresist layer. It is also preferable that the dielectric layer 46 is formed thick enough so as to account for subsequent polishing of the back of the semiconductor substrate 40. The thickness of the dielectric layer 46 is determined by considering the extent to which the thickness of the semiconductor substrate 40 can be reduced by polishing or etching the back of the semiconductor substrate 40 without breaking of the semiconductor substrate 40.

After forming the dielectric layer 46, the back of the semiconductor substrate 40 is polished to reduce the thickness and to prevent signals from coupling between transmission modes. As a result, the dielectric layer 46 can prevent both signal loss caused by dielectric loss and breakage of the semiconductor substrate 40 after the semiconductor substrate 40 is thinned by polishing.

Next, as shown in FIG. 5, a contact hole 50 through which the microstrip line 44 is exposed is formed in the dielectric layer 46. When the dielectric layer 46 is formed of a photosensitive material layer such as a polyimide layer or a photoresist layer, the contact hole 50 is formed by forming a mask (not shown) on the dielectric layer 46 to define a region to be the contact hole 50, exposing using the mask, removing the mask, and developing the resultant structure. However, when the dielectric layer 46 is formed of a non-photosensitive material, a mask is formed on the dielectric layer 46 to define a region to be the contact hole 50, the defined region of the dielectric layer 46 is etched using the mask, and the mask is removed, thereby forming a contact hole 50. However, it is understood that other mechanisms can be used to form the dielectric layer 46 having the contact hole 50 without using the mask. For instance, it is possible to attach a connector to the substrate 40, such as a conductive plug, and forming the dielectric layer 46 around the conductive plug.

The shape and size of the contact hole 50 is not limited as long as the microstrip line 44 can be exposed by the same. In addition, it is understood that the microstrip line 44 may be exclusively exposed by the contact hole 50, or both the semiconductor substrate 40 and the microstrip line 44 may be partially exposed through the contact hole 50.

Next, referring to FIG. 6, a conductive layer is formed on the dielectric layer 46 to form the ground plane 48. A portion of the ground plane 48 is formed to contact the microstrip line 44 through the contact hole 50. As shown in FIG. 6, the ground plane 48 may extend along the sidewall of the contact hole 50 to reach a portion of the microstrip line 44 exposed through the contact hole 50. Alternatively, the ground plane 48 may contact the exposed portion of the microstrip line 44 by, for example, a conductive plug filling the contact hole 50.

As described above, the MMIC according to the present invention has the ground plane connected to the microstrip line through the dielectric layer formed to cover the active and passive devices on the semiconductor substrate. In other words, the ground plane is placed above the devices to be grounded by the ground plane. Thus, the signal loss caused by the dielectric loss can be reduced and the overall manufacturing process can be simplified because there is no need to perform polishing or etching of the back of the semiconductor substrate. Although the semiconductor substrate is processed to be thin enough for the purpose of preventing coupling of signals between transmission modes, due to the dielectric layer formed on the semiconductor substrate to have a thickness large enough to prevent the semiconductor substrate from breaking, the yield does not drop.

While this invention has been particularly shown and described with reference to preferred embodiments thereof, it will be understood by those skilled in the art that various changes in form and details may be made therein. For example, it will be appreciated by those skilled in the art that the dielectric layer may be formed to incorporate air gaps or may be formed as multiple layers. Further, layers may be formed in addition to the dielectric layer such that the ground plane is not directly attached to the dielectric layer, where the ground plane grounds the active device through the dielectric layer.

In addition, the structure of the ground plane according to the present invention can be applied to other devices other than the MMIC. Thus, the spirit and scope of the invention is as defined by the claims and their equivalents, rather than by the preferred embodiments.

What is claimed is:

1. A monolithic microwave integrated circuit comprising:
a semiconductor substrate;
active and passive devices formed on said semiconductor substrate;
a dielectric layer formed to cover said active and passive devices on said semiconductor substrate; and
a ground plane formed on said dielectric layer to ground said active device through said dielectric layer.

2. The monolithic microwave integrated circuit of claim 1, wherein said dielectric layer further comprises a contact hole, and said ground plane grounds said active device through the contact hole.

3. The monolithic microwave integrated circuit of claim 1, wherein said dielectric layer comprises a polymer layer.

4. The monolithic microwave integrated circuit of claim 3, wherein the polymer layer comprises a polyimide layer or a photoresist layer.

5. A method of manufacturing a monolithic microwave integrated circuit, comprising:
forming active and passive devices on a semiconductor substrate such that the active and passive devices are interconnected;
forming a dielectric layer on the semiconductor substrate to cover the active and passive devices; and
forming a ground plane on the dielectric layer to ground the active device.

6. The method of claim 5, wherein the active and passive devices are interconnected by a microstrip line.

7. The method of claim 6, wherein said forming the ground plane comprises:
forming a contact hole in the dielectric layer through which the microstrip line is exposed; and
forming a conductive layer on the dielectric layer in which the contact hole is formed to form the ground plane connected to the microstrip line through the contact hole.

8. The method of claim 5, wherein the dielectric layer comprises a polymer layer.

9. The method of claim 5, wherein the active device comprises a high frequency transistor.

10. The method of claim 6, wherein the active device comprises a high frequency transistor.

11. A monolithic microwave integrated circuit comprising:
a substrate;
a ground plane;
a device disposed between said substrate and said ground plane;
a dielectric layer disposed between said ground plane and said device such that said device is grounded by said ground plane through an electrical pathway through said dielectric layer.

12. The monolithic microwave integrated circuit of claim 11, wherein said dielectric layer comprises a hole through which said ground plane extends to define the electrical pathway to ground said device.

13. The monolithic microwave integrated circuit of claim 11, further comprising a microstrip line disposed on said substrate and electrically connected to said device, wherein said device is grounded by said ground plane using said microstrip line.

14. The monolithic microwave integrated circuit of claim 13, wherein said dielectric layer comprises a hole through which said ground plane extends to contact said microstrip line to define the electrical pathway to ground said device.

15. The monolithic microwave integrated circuit of claim 11, wherein said device comprises an active device.

16. The monolithic microwave integrated circuit of claim 11, wherein said device comprises an active device, and further comprising a passive device disposed on said substrate and electrically connected to the active device.

17. The monolithic microwave integrated circuit of claim 14, wherein said device comprises an active device.

18. The monolithic microwave integrated circuit of claim 17, further comprising a passive device disposed on said substrate and electrically connected to the active device using said microstrip line.

19. A method pf manufacturing a monolithic microwave integrated circuit, comprising:
forming a dielectric layer on a substrate to cover a device formed on the semiconductor substrate; and
forming a ground plane to ground the device through the dielectric layer.

20. The method of claim 19, wherein said forming a ground plane comprises forming a connection between the device and the ground place through the dielectric layer.

21. The method of claim 20, wherein the forming the connection comprises:
forming a hole through the dielectric layer, and
forming an electrical pathway passing through the hole and connecting the device and the ground plane.

22. The method of claim 21, wherein the forming the hole comprises:
forming a mask on the dielectric layer, where the dielectric layer is photosensitive,
exposing the dielectric layer using the mask,
removing the mask, and
developing the dielectric layer after removing the mask.

23. The method of claim 21, wherein the forming the hole comprises:
forming a mask on the dielectric layer,
etching the dielectric layer using the mask, and
removing the mask.

24. The method of claim 20, wherein a microstrip line is formed on the substrate, and the device is connected to the ground plane using the microstrip line.

25. The method of claim 24, wherein the forming the connection comprises:
forming a hole through the dielectric layer to expose a portion of the microstrip line, and
forming an electrical pathway passing through the hole and connecting the portion of the microstrip line and the ground plane such that the device is grounded by the ground plane.

26. The method of claim 25, wherein additional devices are formed on the substrate and are connected to the device using the microstrip line.

27. The method of claim 25, wherein the device is an active device.

28. The method of claim 26, wherein the device is an active device, and one of the additional devices is a passive device.

29. The method of claim 19, wherein the substrate comprises a III-V compound semiconductor substrate.

30. The method of claim 19, wherein the substrate comprises an SiGe semiconductor substrate.

31. The method of claim 19, further comprising forming the device on the substrate.

32. The method of claim 31, wherein said forming the device on the substrate comprises:
performing selective implantation of the substrate with GaAs ions,
activating the GaAs ions to form a channel region,
etching the substrate to form a recess in the substrate, and
forming a metal gate in the recess.
